(19) United States
(12) Patent Application Publication
(10) Pub. No.: US 2016/0231605 A1
(43) Pub. Date: Aug. 11, 2016

(54) RGBW TFT LCD HAVING REDUCED HORIZONTAL CROSSTALK

(71) Applicant: Century Technology (Shenzhen) Corporation Limited, Shenzhen (CN)

(72) Inventors: WEN-QIANG YU, Shenzhen (CN); MING-TSUNG WANG, New Taipei (TW); CHIH-CHUNG LlU, New Taipei (TW); YI-HSIU CHENG, New Taipei (TW)

(21) Appl. No.: 14/690,959

(22) Filed: Apr. 20, 2015

(30) Foreign Application Priority Data
Feb. 9, 2015 (CN) 201510065080.3

(51) Int. Cl. G02F 1/1368; G02F 1/1335; H01L 27/12; G02F 1/1362

(52) U.S. Cl. CPC G02F 1/1368; G02F 1/136286; G02F 1/133514; H01L 27/1255

(57) ABSTRACT

An RGBW TFT LCD includes a backlight module, a first polarizer, a TFT array substrate, a liquid crystal layer, a color filter and a second polarizer. The TFT array substrate includes a plurality of pixels each consisting of a red sub-pixel, a green sub-pixel, a blue sub-pixel and a white sub-pixel arranged in a 2×2 matrix. Data lines and dummy data lines are alternately arranged wherein each column of the sub-pixels is arranged between a data line and a dummy data line which is in electrical connection with a lower common electrode in electrical connection with a storage capacitor for each sub-pixel. Two scan lines are located between two neighboring rows of the sub-pixels. The sub-pixels are driven by either column inversion or dot inversion. The four sub-pixels of a pixel are electrically connected to a common data line and a respective scan line.

### CROSS-REFERENCE TO RELATED APPLICATIONS

This application claims priority to Chinese Patent Application No. 201510065080.3 filed on Feb. 9, 2015, the contents of which are incorporated by reference herein.

### FIELD

The subject matter herein generally relates to a TFT LCD (thin film transistor liquid crystal display), and particularly to a TFT LCD having an RGBW (red, green, blue, white) TFT array substrate with a reduced horizontal crosstalk.

### BACKGROUND

TFT LCDs have become the most popular flat displays since they have advantages of compactness, low heat generation, long life and visual comfort. In general a TFT LCD includes a backlight module, a first polarizer, a TFT array substrate, a liquid crystal layer, a color filter and a second polarizer. The TFT array substrate forms a plurality of pixels thereon. The liquid crystal layer contains a plurality liquid crystals therein. Originally, each pixel includes three sub-pixels, i.e., a red sub-pixel, a green sub-pixel, and a blue sub-pixel. For such an RGB TFT LCD, the backlight module needs consuming more power in order to have sufficient light passing through the color filter.

To overcome the disadvantage of the RGB TFT LCD, an RGBW TFT LCD is developed, in which each pixel includes a red sub-pixel, a green sub-pixel, a blue sub-pixel, and a white sub-pixel. A transparent area corresponding to the white sub-pixel is defined in the color filter, whereby a light transmittance of the color filter is improved, and the power consumption required by the backlight module can be reduced.

However, for the RGBW TFT LCD, it confronts a problem of horizontal crosstalk which does not occur in the RGB TFT LCD. When the RGBW TFT LCD shows a one-colored segment (for example, an entirely green segment), every pixel in the segment has the same polarity, whereby Vcom couples cannot offset from each other, whereby a horizontal crosstalk happens which results in an uneven grey level beside the green segment. Here Vcom couple means a couple between data lines and an upper common electrode, i.e., CF (color filter) layer Vcom, for providing a bias across the liquid crystals in the liquid crystal layer.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is diagrammatic view of an RGBW TFT LCD in accordance with the present disclosure.

FIG. 2 is a diagrammatic view of a TFT array substrate of the RGBW TFT LCD in accordance with a first embodiment of the present disclosure.

FIG. 3 is a circuit diagram of a sub-pixel of the TFT array substrate of the RGBW TFT LCD of FIG. 2.

FIG. 4 is a diagrammatic view of a TFT array substrate of the RGBW TFT LCD in accordance with a second embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” means “including, but not necessarily limited to”; it specifically indicates open-ended inclusion or membership in a so-described combination, group, series and the like.

The present disclosure is described in relation to an RGBW (red-green-blue-white) TFT (thin film transistor) LCD (liquid crystal display) 1, which can be used in a screen of a mobile phone for example a smart phone, a monitor of a computer, a screen of a laptop, a screen of a television set, or a screen of a tablet computer.

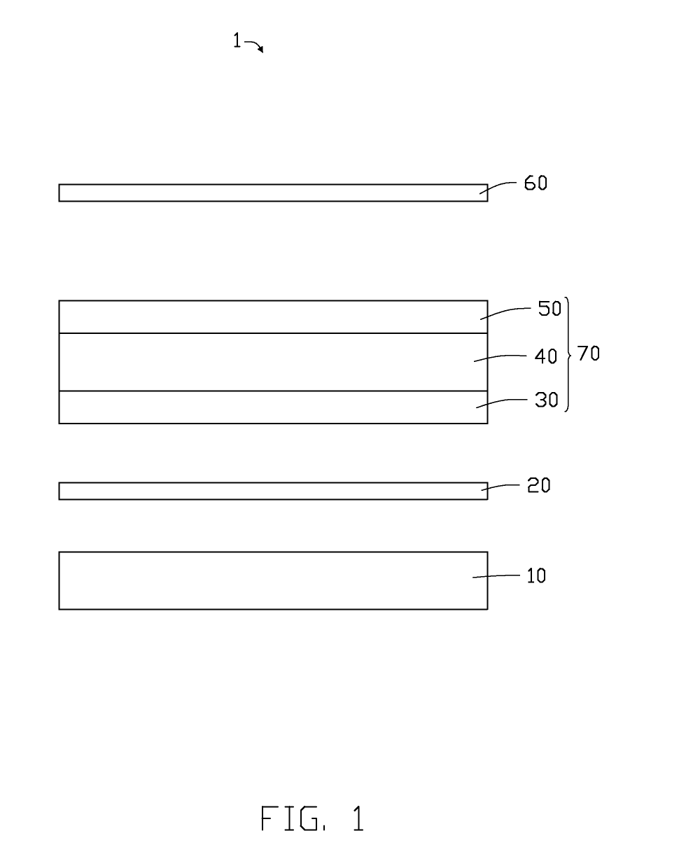

FIG. 1 illustrates a diagrammatic view of the RGBW TFT LCD 1 having, along an upward direction, a backlight module 10, a first polarizer 20, a TFT array substrate 30, a liquid crystal layer 40, a color filter 50 and a second polarizer 60. The TFT array substrate 30, the liquid crystal layer 40, the color filter 50 and a driver circuit assembly (not shown) in combination construct an LCD module 70. The backlight module 10, the first polarizer 20, the TFT array substrate 30, the liquid crystal layer 40, the color filter 50 and the second polarizer 60 each have a substantially rectangular cross section.

The backlight module 10 can include LEDs (light emitting diodes) or CCFLs (cold cathode fluorescent lamps) as a light source for generating white light radiating upwardly through the first polarizer 20, the TFT array substrate 30, the liquid crystal layer 40, the color filter 50 and finally the second polarizer 60. The first polarizer 20 polarizes the light, which means that only the orthogonal direction of light is allowed to pass through the first polarizer 20 to reach the TFT array substrate 30. The liquid crystal layer 40 includes a plurality of liquid crystals therein. An direction of arrangement of the liquid crystals can be changed in accordance with a change of a bias across the liquid crystal layer 40, thereby to adjust amount of light through the liquid crystal layer 40. The color filter 50 in accordance with the present disclosure is an RGBW color filter and has a plurality of pixels each including a green sub-pixel, a red sub-pixel, a blue sub-pixel and a white sub-pixel. The white sub-pixels are transparent whereby a transmittance of the color filter 50 can be increased, in comparison with the RGB color filter, whereby the power needed by the backlight module 10 can be decreased. The function of the second polarizer 60, similar to the first polarizer 20, is used to allow only the orthogonal direction of light to pass therethrough.

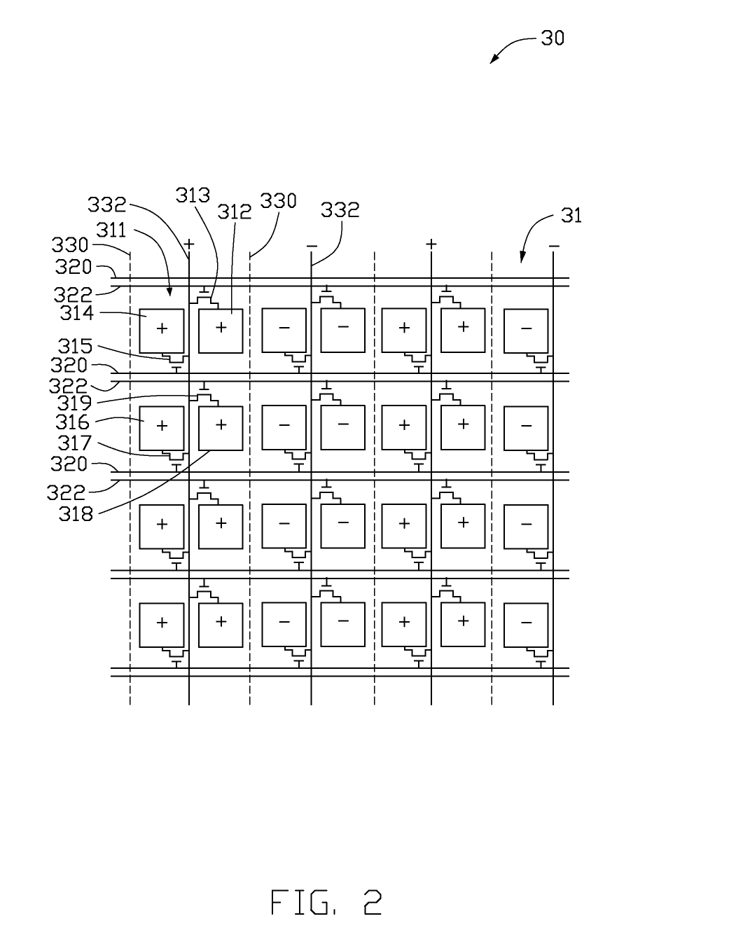

Referring to FIG. 2, a circuit 31 of the TFT array substrate 30 of the RGBW TFT LCD 1 in accordance with a first embodiment of the present disclosure is shown. The circuit 31 is arranged in a manner than it is driven by column inversion and includes a plurality of pixels 311 arranged in a matrix. Each pixel 311 consists of a red sub-pixel 312, a green sub-pixel 314, a blue sub-pixel 316 and a white sub-pixel 318. The four sub-pixels 312, 314, 316, 318 are arranged in a substantially square matrix (i.e., 2×2 matrix) with the red and green sub-pixels 312, 314 arranged in a same row and the blue and white sub-pixels 316, 318 arranged in a neighboring same row, while the red and white sub-pixels 312, 318 arranged in a same column and the green and blue sub-pixels 314, 316 arranged in a neighboring same column. In their respective same row, the red and green sub-pixels 312, 314 are alternated, and the blue and white sub-pixels 316, 318 are alternated. In their respective same column, the red and white sub-pixels 312, 318 are alternated, and the green and blue sub-pixels 314, 316 are alternated.

Along the column direction (horizontal direction), dummy data lines 330 and data lines 332 are parallel to each other and alternately arranged. Each of the dummy data and data lines 330, 332 is located between two columns of the sub-pixels. The dummy data line 330 is arranged between two adjacent pixels, and the data line 332 is arranged between two adjacent sub-pixels of each pixel. Two scan lines 320, 322 are located between two rows of the sub-pixels. The scan lines 320, 322 are orthogonal to and intersecting with the dummy data and data lines 330, 332. The data lines 332 and the scan lines 320, 322 are electrically coupled to the sub-pixels via the thin film transistors, while the dummy data lines 330 are electrically coupled to the sub-pixels through a lower common electrode (Array Vcom) and storage capacitors (Csts).

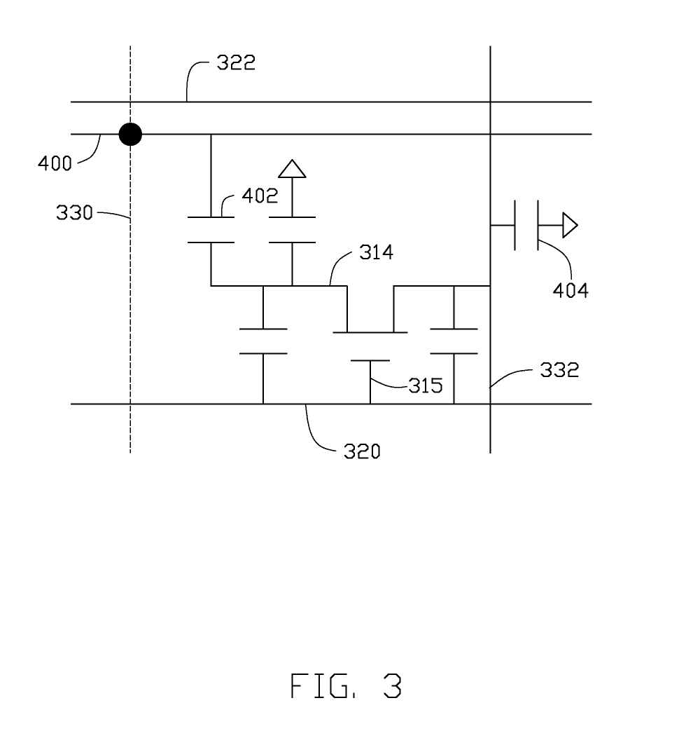

Referring to FIG. 3, taking the green sub-pixel 314 of FIG. 2 as an example, the dummy data line 330 in connection therewith electrically couples to a lower common electrode (i.e., Array Vcom) 400 in electrical coupling with a storage capacitor (i.e., Cst) 402 for the sub-pixel 314 whereby a resistance of the lower common electrode 400 can be lowered to shorten the charging time of the storage capacitor 402 thereby to improve the evenness of the display quality throughout the RGBW TFT LCD 1. The storage capacitors 402 and the lower common electrode 400 therefor are well known by those skilled in the art; detailed descriptions thereof are omitted here.

Returning to FIG. 2, the red sub-pixel 312 is electrically connected with one of the scan lines 322 immediately thereabove and one of the data lines 332 adjacent thereto by a thin film transistor 313. The thin film transistor 313 has a source electrode (not labeled) in electrical coupling with the data line 332, a gate electrode (not labeled) in electrical coupling with the scan line 322 and a drain electrode (not labeled) in electrical coupling with a pixel electrode (not labeled) of the red sub-pixel 312.

The green sub-pixel 314 is electrically connected with one of the scan lines 320 immediately therebelow and one of the data lines 332 adjacent thereto by a thin film transistor 315, wherein the connected data line 332 is commonly connected with the red sub-pixel 312. The thin film transistor 315 has a source electrode (not labeled) in electrical coupling with the data line 332, a gate electrode (not labeled) in electrical coupling with the scan line 320 and a drain electrode (not labeled) in electrical coupling with a pixel electrode (not labeled) of the green sub-pixel 314.

The blue sub-pixel 316 is electrically connected with one of the scan lines 320 immediately therebelow and one of the data lines 332 adjacent thereto by a thin film transistor 317, wherein the connected data line 332 is commonly connected with the red and green sub-pixels 312, 314. The thin film transistor 317 has a source electrode (not labeled) in electrical coupling with the data line 332, a gate electrode (not labeled) in electrical coupling with the scan line 320 and a drain electrode (not labeled) in electrical coupling with a pixel electrode of the blue sub-pixel 316.

The white sub-pixel 318 is electrically connected with one of the scan lines 322 immediately thereabove and one of the data lines 332 adjacent thereto by a thin film transistor 319, wherein the connected data line 332 is commonly connected with the red, green and blue sub-pixels 312, 314, 316. The thin film transistor 319 has a source electrode (not labeled) in electrical coupling with the data line 332, a gate electrode (not labeled) in electrical coupling with the scan line 322 and a drain electrode (not labeled) in electrical coupling with a pixel electrode of the white sub-pixel 318. Since in this embodiment, the sub-pixels are driven by column inversion, along each of the data lines 332, the sub-pixels in electrical connection therewith have the same polarity.

In operation, the data lines 332 are alternately supplied with positive voltage and negative voltage, whereby the red (green, blue, white) sub-pixel 312 (314, 316, 318) and a neighboring red (green, blue, white) sub-pixel in the same row have opposite polarities. Accordingly when the RGBW TFT LCD 1 is required to show a single color of one of the red, green blue and white colors, the pixels 311 in two neighboring columns have opposite polarities, i.e., one being positive and the other being negative. By such arrangement, the coupling effects caused by capacitors (i.e., Cscs) 404 (FIG. 3) of each two neighboring columns of the pixels 311 on the waveform of an upper common electrode (i.e., CF (color filter) layer Vcom, not shown) can offset from each other to obviate the horizontal crosstalk, wherein the capacitor 404 (FIG. 3) is a capacitor interconnecting a corresponding data line 332 and the upper common electrode for supplying a bias across the liquid crystal layer 40. The upper common electrode and the capacitors 404 (FG 3) for connecting the upper common electrode and the data lines 332 are well known by those skilled in the art; detailed descriptions thereof are omitted here.

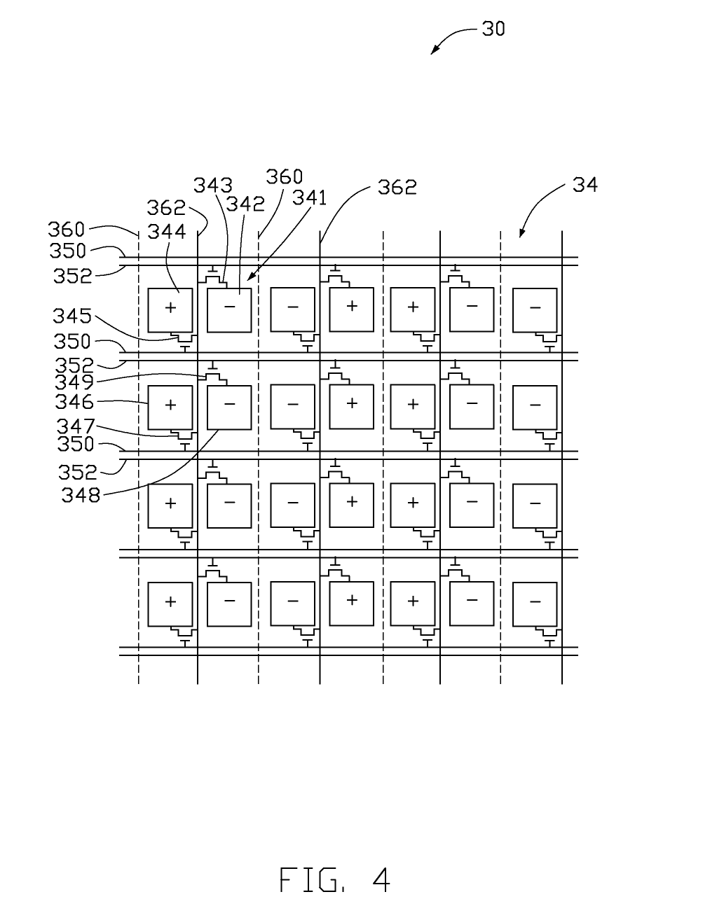

Referring to FIG. 4, a circuit 34 of the TFT array substrate 30 of the RGBW TFT LCD 1 in accordance with a second embodiment of the present disclosure is shown. The circuit 34 is arranged in a manner that it is driven by dot inversion and includes a plurality of pixels 341 arranged in a matrix. Each pixel 341 consists of a red sub-pixel 342, a green sub-pixel 344, a blue sub-pixel 346 and a white sub-pixel 348. The four sub-pixels 342, 344, 346, 348 are arranged in a substantially square matrix (i.e., 2×2 matrix) with the red and green sub-pixels 342, 344 arranged in a same row and the blue and white sub-pixels 346, 348 arranged in a neighboring same row, while the red and white sub-pixels 342, 348 arranged in a same column and the green and blue sub-pixels 344, 346 arranged in a neighboring same column.

Along the column direction (horizontal direction), dummy data lines 360 and data lines 362 are parallel to each other and alternately arranged. Each of the dummy data and data lines 360, 362 is located between two columns of the sub-pixels. The dummy data line 360 is arranged between two adjacent pixels, and the data line 362 is arranged between two adjacent sub-pixels of each pixel. Two scan lines 350, 352 are located between two rows of the sub-pixels. The scan lines 350, 352 are orthogonal to and intersecting with the dummy data and data lines 360, 362. The data lines 362 and the scan lines 350, 352 are electrically coupled to the sub-pixels, while the dummy data lines 360 do not electrically couple with the sub-pixels. The dummy data lines 360 electrically couple to the lower common electrode (not shown) in electrically coupling with the storage capacitors (not shown) whereby a resistance of the lower common electrode can be lowered to shorten the charging time of the storage capacitors thereby to improve the evenness of the display quality throughout the RGBW TFT LCD 1.

The red sub-pixel 342 is electrically connected with one of the scan lines 352 immediately thereabove and one of the data lines 362 adjacent thereto by a thin film transistor 343. The thin film transistor 343 has a source electrode (not labeled) in electrical coupling with the data line 362, a gate electrode (not labeled) in electrical coupling with the scan line 352 and a drain electrode (not labeled) in electrical coupling with a pixel electrode (not labeled) of the red sub-pixel 342.

The green sub-pixel 344 is electrically connected with one of the scan lines 350 immediately therebelow and one of the data lines 362 adjacent thereto by a thin film transistor 345, wherein the connected data line 363 is commonly connected with the red sub-pixel 342. The thin film transistor 345 has a source electrode (not labeled) in electrical coupling with the data line 362, a gate electrode (not labeled) in electrical coupling with the scan line 350 and a drain electrode (not labeled) in electrical coupling with a pixel electrode (not labeled) of the green sub-pixel 344.

The blue sub-pixel 346 is electrically connected with one of the scan lines 350 immediately therebelow and one of the data lines 362 adjacent thereto by a thin film transistor 347, wherein the connected data lines 362 commonly connected with the red and green sub-pixels 342, 344. The thin film transistor 347 has a source electrode (not labeled) in electrical coupling with the data line 362, a gate electrode (not labeled) in electrical coupling with the scan line 350 and a drain electrode (not labeled) in electrical coupling with a pixel electrode of the blue sub-pixel 346.

The white sub-pixel 348 is electrically connected with one of the scan lines 352 immediately thereabove and one of the data lines 362 adjacent thereto by a thin film transistor 349, wherein the connected data line 362 is commonly connected with the red, green and blue sub-pixels 342, 344, 346. The thin film transistor 349 has a source electrode (not labeled) in electrical coupling with the data line 362, a gate electrode (not labeled) in electrical coupling with the scan line 352 and a drain electrode (not labeled) in electrical coupling with a pixel electrode of the white sub-pixel 348. Since in this embodiment, the sub-pixels are driven by dot inversion, along each of the data lines 332, the sub-pixels in electrical connection therewith have alternately opposite polarities, while the alternating signals supplied to two neighboring data lines are shifted from each other by 180 degrees.

In operation, since the data lines 362 are driven by dot inversion, the red (green, blue, white) sub-pixel 342 (344, 346, 348) and a neighboring red (green, blue, white) sub-pixel in the same row have opposite polarities. Accordingly when the RGBW TFT LCD 1 is required to show a single color of one of the red, green blue and white colors, the pixels 341 in two neighboring columns have opposite polarities, i.e., one being positive and the other being negative. By such arrangement, the coupling effects caused by the liquid-crystal capacitors (Clcs, not shown) of each two neighboring columns of the pixels on the waveform of the upper common electrode (Com, not shown) can offset from each other to obviate the horizontal crosstalk.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in particular the matters of shape, size and arrangement of parts within the principles of the present disclosure, up to and including the full extent established by the broad general meaning of the terms used in the claims.

What is claimed is:

1. A thin film transistor (TFT) liquid crystal display (LCD) comprising:
a TFT array substrate comprising a plurality of pixels arranged in a matrix, each pixel of the plurality of pixels comprising a plurality of sub-pixels including at least a red sub-pixel, a green sub-pixel, a blue sub-pixel and a white sub-pixel arranged in a 2×2 matrix, wherein two neighboring same colored sub-pixels in a same row of the plurality of sub-pixels have opposite polarities when the TFT LCD provides an output having a color the same as a color of the two neighboring same colored sub-pixels; and
a liquid crystal layer over the TFT array substrate.

2. The TFT LCD of claim 1, wherein the TFT array substrate comprises a plurality of data lines and a plurality of dummy data lines alternating with each other, each of the data lines and dummy data lines is located between two neighboring columns of the sub-pixels, each dummy data line is arranged between two adjacent pixels, each data line is arranged between two adjacent sub-pixels of each pixel, two scan lines being located between two neighboring rows of the sub-pixels, a first thin film transistor electrically coupling the red sub-pixel with one of the scan lines immediately thereabove and one of the data lines adjacent thereto, a second thin film transistor electrically coupling the green sub-pixel with one of the scan lines immediately therebelow and said one of the data lines, a third thin film transistor electrically coupling the blue sub-pixel with one of the scan lines immediately therebelow, and said one of the data lines, and a fourth thin film transistor electrically coupling the white sub-pixel with one of the scan lines immediately thereabove and said one of the data lines.

3. The TFT LCD of claim 2, wherein the sub-pixels are electrically driven by column inversion whereby along a data line, the sub-pixels in electrical connection therewith have the same polarity.

4. The TFT LCD of claim 3, wherein two neighboring data lines have opposite polarities.

5. The TFT LCD of claim 4, wherein each of the first, second, third and fourth thin film transistors has a source electrode in electrical connection with a corresponding data line, a gate electrode in electrical connection with a corresponding scan line and a drain electrode in electrical connection with a pixel electrode of a corresponding sub-pixel.

6. The TFT LCD of claim 5, wherein the pixel electrodes are configured for electrically connecting with a first common electrode via a plurality of capacitors, the first common electrode being configured for applying a bias across the liquid crystal layer.

7. The TFT LCD 6, wherein the dummy data lines are configured for electrically connecting with a second common electrode which is configured for electrically connecting with storage capacitors for the sub-pixels.

8. The TFT LCD of claim 2, wherein the sub-pixels are electrically driven by dot inversion whereby along a data line, the sub-pixels in electrical connection therewith have alternately opposite polarities.

9. The TFT LCD of claim 8, wherein alternating signals supplied to two neighboring data lines are shifted from each other by 180 degrees.

10. The TFT LCD of claim 9, wherein each of the first, second, third and fourth thin film transistors has a source electrode in electrical connection with a corresponding data line, a gate electrode in electrical connection with a corresponding scan line and a drain electrode in electrical connection with a pixel electrode of a corresponding sub-pixel.

11. The TFT LCD of claim 10, wherein the pixel electrodes are configured for electrically connecting with a first common electrode via a plurality of capacitors, the first common electrode being configured for applying a bias across the liquid crystal layer.

12. The TFT LCD of claim 11, wherein the dummy data lines are configured for electrically connecting with a second common electrode which is configured for electrically connecting with storage capacitors for the sub-pixels.

13. The TFT LCD of claim 1 further comprising a color filter over the liquid crystal layer, wherein the color filter has a plurality of pixels each comprising a red sub-pixel, a green sub-pixel, a blue sub-pixel and a white sub-pixel which is transparent.

14. A thin film transistor (TFT) array substrate for a thin film transistor (TFT) liquid crystal display (LCD) comprising:
a plurality of data lines;
a plurality of pairs of scan lines intersecting with and orthogonal to the data lines;
a plurality of pixels each comprising a red sub-pixel, a green sub-pixel, a blue sub-pixel and a white sub-pixel wherein the red and green sub-pixels are arranged in a plurality of first rows, the blue and white sub-pixels are arranged in a plurality of second rows alternating with the first rows, the red and white sub-pixels are arranged in a plurality of first columns and the green and blue sub-pixels are arranged in a plurality of second columns alternating with the first columns;
wherein the sub-pixels of a pixel are electrically to a common data line between one of the first columns having the red and white sub-pixels and a neighboring second column having the green and blue sub-pixels, each pair of scan lines is located between two neighboring rows of the sub-pixels, the red sub-pixel is electrically connected to one of the scan lines immediately thereabove, the green sub-pixel is electrically connected to one of the scan lines immediately therebelow, the blue sub-pixel is electrically connected to one of the scan lines immediately therebelow and the white sub-pixel is electrically connected to one of the scan lines immediately thereabove; and
wherein two neighboring same colored sub-pixels in a same row of the sub-pixels have opposite polarities when the TFT LCD is operated to output a screen having a color the same as the color of the two neighboring same colored sub-pixels.

15. The TFT array substrate of claim 14 further comprising a plurality of dummy data lines parallel to and alternating with the data lines.

16. The TFT array substrate of claim 15, wherein the dummy data lines are configured for electrically connecting with a first common electrode configured for electrically connecting with storage capacitors for the sub-pixels.

17. The TFT array substrate of claim 15, wherein the sub-pixels are driven by column inversion, whereby along a data line, the sub-pixels in electrical connection therewith have a same polarity, and wherein two neighboring data lines have opposite polarities.

18. The TFT array substrate of claim 15, wherein the sub-pixels are driven by dot inversion, whereby along a data line, the sub-pixels in electrical connection therewith have alternately opposite polarities.

19. The TFT array of claim 15, wherein each of the red, green, blue and white sub-pixels is connected to the common data line by a source electrode of a transistor and a corresponding scan line by a gate electrode of the transistor, and has a pixel electrode electrically connecting with a drain electrode of the transistor.

20. The TFT array of claim 19, wherein the pixel electrodes are configured for electrically connecting with a second common electrode via a plurality of capacitors, the second common electrode being configured for applying a bias across a liquid crystal layer of the TFT LCD.
